(19) United States
(12) Patent Application Publication
(10) Pub. No.: US 2009/0206677 A1
(43) Pub. Date: Aug. 20, 2009

(54) HIGH VOLTAGE SWITCHING DEVICE

(76) Inventor: John G. Kulpin, Madison, WI (US)

Correspondence Address: WISCONSIN ALUMNI RESEARCH FOUNDATION, C/O BOYLE FREDRICKSON S.C, 840 North Plankinton Avenue, Milwaukee, WI, 53203, US

(21) Appl. No.: 12/031,207

(22) Filed: Feb. 14, 2008

(51) Int. Cl. G08B 5/36; H03K 3/01; H01H 9/54

(52) U.S. Cl. 307/113; 327/303; 340/815.45

(57) ABSTRACT

A modulator switch composed of stacks of high voltage switching devices connected in series are fired substantially simultaneously to provide pulsed, high voltage switching capable of providing megajoules of energy. The switching devices are fired by a trigger box that is clocked to provide a pulsed signal to each of the switching devices. The trigger box generally consists of a triggering or driver circuit and a pulse generating circuit. These circuits are electrically isolated from one another using suitable shielding and spacing. The pulsed output of the trigger box is fed to the switching devices across low inductance twisted cabling that is passed through toroidal transformers connected to the inputs of the switching devices. Varistors are clamped across each stack of switching devices to provide over-voltage protection for the switching devices.

### REFERENCE TO GOVERNMENT GRANT

This invention was made with United States government support awarded by the Department of Energy (DE-FC02-05ER54814, 144-NH87). The United States has certain rights in this invention.

### FIELD OF THE INVENTION

This invention relates generally to high voltage switching devices and, more particularly, to a high voltage phase control thyristor switch composed of multiple stacks of switching devices that are switched simultaneously.

### BACKGROUND AND SUMMARY OF THE INVENTION

High voltage switching devices are used in a number of applications, such as RADAR systems, medical imaging devices, nuclear power generators, water management systems, and particle accelerators, as well as various research applications, such as fusion energy research and plasma astrophysics. These and other applications utilize specialized switching devices specifically designed to switchably connect a load to a high voltage source, e.g. greater than 50 kV. One exemplary high voltage switching device is an ignitron switch tube.

Ignitron switch tubes are commonly used as modulator switches for high potentials, including those at 50 kV and above. While generally effective for lower high voltage applications, for those applications in which it is necessary to switch voltages in excess of 100 kV at 10 kJ, conventional ignitron tubes pose some problems.

Ignitron tubes can produce large amounts of electrical noise when switching large potentials. This can negatively affect logic level electronics and equipment proximate the tubes. Ignitron tubes also require conditioning in order to trigger properly and withstand their rated voltage potential. One skilled in the art will appreciate that this requires proper thermal management around both ends of the tube as well as hipotting to insure proper hold-off potential. Without the proper conditioning, the ignitron tubes can trigger intermittently and greatly reduce system reliability and predictability.

Additionally, the commercial availability of ignitron tubes is increasingly more limited. Ignitron tubes are costly to manufacture and contain mercury. As a result, manufactures are now focusing their design and manufacturing efforts on solid state based switching devices, such as thyristors or IGBTs. The applicability of these solid-state alternatives for high voltage, high energy applications however have been limited.

For example, researchers at the University of Wisconsin, Madison, are investigating hot plasmas as part of fusion energy research. As part of this investigation, investigators use the Madison Symmetric Torus (MST) to produce plasma from hydrogen gas. The energy necessary to sufficiently heat the hydrogen gas is extremely high (on the order of several megajoules). To meet this energy demand, many types of pulsed power systems have been developed. For example, one proposed pulsed power system is capable of providing pulsed energy at 100 kV, 70 kJ. Conventionally, ignitron tubes have been used to satisfy the aforementioned voltage and energy, but, as described above, ignitron tubes pose some drawbacks. Alternately, stacked solid-state devices, such as thyristors, may be used, but to switch such a high voltage that produces the necessary energy to heat the hydrogen gas, the stacked devices need a specialized triggering or driving circuit. Thus, for thyristors to be effective as an alternative to ignitrons, a suitable drive circuit that has heretofore been unavailable is needed.

According to one representative embodiment of the present invention, a drive circuit for triggering a stack of thyristors to meet the high energy demands of the MST and other high voltage, high energy applications is provided. The stack of thyristors includes four modules with each module containing six thyristors. Each thyristor is rated for 6500 volts peak potential, with a fully assembled unit of six rated to 39 kV. Combining four fully assembled modules together gives a peak rating of 156 kV. Moreover, since each thyristor is capable of handling 350 amperes of average current, the stack is capable of switching megajoules of energy. Snubber capacitors, rated at 30 kV and 400 pf, are connected across each thyristor to damp transients. Each thyristor, which is a three terminal device consisting of a gate, anode, and cathode, also has a toroidal transformer at its gate with a low ohm power resistor in series with it attached from toroid to gate. A zener diode is connected across each gate and cathode to provide overvoltage protection for the thyristor gate input. Metal oxide varistors are attached across each group of thyristors to clamp voltages in excess of 35 kV. Thus, at a potential of 100 kV, no group of thyristors sees more than 25 kV. Ballast resistors are also provided to provide precise voltage division during switch operation.

The driver or triggering circuit uses an AC transformer and full-wave rectifier to charge a capacitor bank to a suitable charge, e.g., approximately 525 VDC. The driver circuit has a fiber optic receiver that accepts a clock trigger input pulse that latches a silicon controlled rectifier (SCR) to the capacitor bank to provide a current pulse that is fed to each of the thyristors. In this representative embodiment, a peak output current pulse of approximately 45 A with a rise time of 1.0 microsecond and a decay of 150 microseconds may be realized.

The output pulse of the trigger circuit is run through each of the toroidal transformers that are individually wired into the gates of the thyristors. In this representative embodiment, the toroidal transformers are five turn transformers capable of converting a 45 A, 525 V waveform into an 8.5 A, low voltage pulse at each thyristor gate input. The output pulse triggers the thyristors simultaneously.

It is therefore an object of the invention to provide a solid-state switching device and associated trigger circuit capable of switching a high voltage potential and providing megajoules of energy.

It is another object of the invention to provide a drive circuit for a stacked arrangement of thyristors that triggers each of the thyristors simultaneously.

In yet a further representative embodiment, the fiber optic receiver and its clocked input are electrically shielded and spaced from the pulse generating components of the drive circuit. For example, copper shielding may be used. Transient voltage suppressors (TVS) and varistors may also be used to provide overvoltage protection.

In yet another representative embodiment, low inductance twisted cabling is used to deliver a precisely controlled pulse through the toroidal transformers. In one embodiment, the low inductance twisted cabling is effective in transmitting a trigger pulse with a rise time of 1.0 microsecond.

Therefore, in accordance with one aspect of the invention, a driver circuit is configured to fire multiple thyristors substantially simultaneously, and includes a power input, a capacitor bank electrically connected to the power input, and a silicon controlled rectifier electrically associated with the capacitor bank. The driver circuit further includes a clocked trigger that latches the rectifier to the capacitor bank to provide a pulsed input trigger to each of the multiple thyristors simultaneously.

In accordance with another aspect, the present invention is directed to a switching device configured to switchably connect a load to a power supply of at least 100 kV. The switching device includes a plurality of switching devices connected in series, each of the switching devices having an input connected to the power supply, an output connected to a load, and a gate for triggering. The switching device further includes a plurality of transformers, with each coupled to the gate of a respective switching device. A driver circuit is connected to the plurality of transformers and provides a driving pulse to the plurality of transformers substantially simultaneously.

According to yet another aspect, the present invention is directed to a high power modulator switch for switching voltages in excess of 50 kV. The switch includes groups of thyristors connected between a power supply and a load, and a toroidal transformer connected to the gate of each thyristor. The switch includes a driver circuit having a clocked input and an output connected through each of the toroidal transformers. The driver circuit provides a pulse through each toroidal transformer so that each thyristor is switched from a non-conductive state to a conductive state substantially simultaneously.

Other aspects, features, and advantages of the invention will become apparent to those skilled in the art from the following detailed description and accompanying drawings. It should be understood, however, that the detailed description and specific examples, while indicating preferred embodiments of the present invention, are given by way of illustration and not of limitation. Many changes and modifications may be made within the scope of the present invention without departing from the spirit thereof, and the invention includes all such modifications.

### BRIEF DESCRIPTION OF THE DRAWINGS

The drawings furnished herewith illustrate a preferred construction of the present invention in which the above advantages and features are clearly disclosed as well as others which will be readily understood from the following description of the illustrated embodiment.

In the drawings:

FIG. 1 is a schematic representation of a phase control modulator switch composed of a trigger circuit and stacked thyristors;

FIG. 2 is a schematic representation of a stacked thyristor and associated circuitry; and

FIG. 3 is a schematic representation of the trigger circuit.

### DETAILED DESCRIPTION OF THE DRAWINGS

The present invention will be described with respect to a phase controlled switch modulator operable with a high voltage power source and capable of producing megajoules of energy. In one embodiment, the switch is used to connect a load to a 100 kV source and produce 10 kJ or more of energy. As will be described, in one embodiment, the modulator switch includes stacks of thyristors that are simultaneously triggered by a drive circuit; however, it is understood that the present invention may be embodied in other switching devices, such as IGBTs. As will be made further apparent from the description below, the present invention provides an alternative to ignitron tubes for high voltage switching and other pulse power applications. In this regard, the present invention provides a reduction in electrical noise, increased reliability, lower cost and other advantages compared to conventional ignitron tubes.

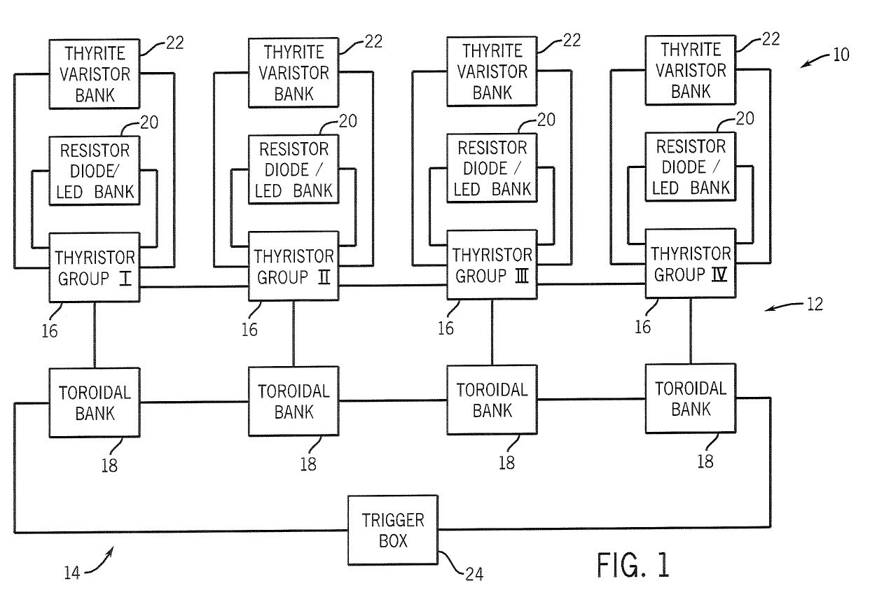

FIG. 1 shows a phase control modulator switch for use with high voltage and pulsed applications according to one embodiment of the present invention. The modulator switch 10 can be characterized as comprising two segments: a pulse generating segment 12 and a triggering segment 14. The pulse generating segment 12 is composed of multiple thyristors arranged into multiple stacks 16 connected in series. In the illustrated embodiment, the switch 10 includes four stacks 16 of thyristors with each stack having six thyristors connected in series. Thus, in this embodiment, the switch 10 is comprised of twenty-four thyristors; however, it is understood that other embodiments may include more or less than twenty-four thyristors arranged into more or less than four groups. Each thyristor is associated with a toroidal transformer and thus, in this regard, each stack 16 of thyristors is associated with a toroidal transformer bank 18.

Additionally, each thyristor has one or more LEDs associated therewith to provide visual indication of the operation status of the thyristors. In this regard, each thyristor stack 16 has a corresponding LED bank 20, as well as ballast resistors and reverse protection diodes, the functionality of which will be described in greater detail below. Overvoltage protection for the thyristors of each stack 16 is provided by a varistor bank 22.

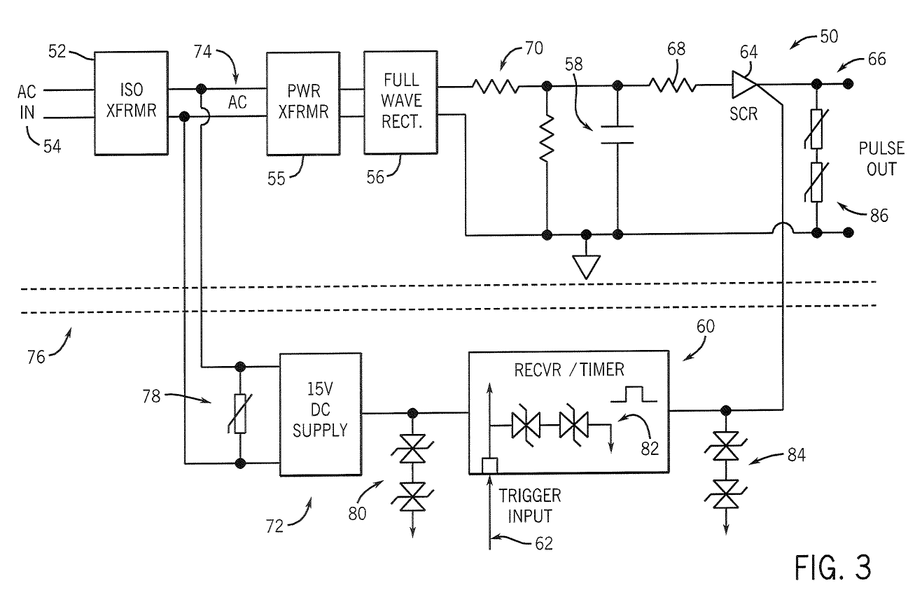

The trigger segment 14 includes a trigger box 24 that has a driver circuit for simultaneously triggering each of the thyristors, as will be described in greater detail below. More particularly, the driver circuit contained within the trigger box 24 is shown at and will be described with respect to FIG. 3.

As noted above, in one embodiment, each stack 16 has six thyristors clamped together to form a single high voltage unit, and each thyristor is capable of handling 350 A of average current. Each thyristor is rated for 6500 V peak potential, with a fully assembled unit of six therefore rated for 39 kV peak potential. Thus, the combined four stacks 16 of thyristors provide a total peak potential rating of 156 kV. The combined stacks therefore provide an assembled switch 10 capable of switching megajoules of energy.

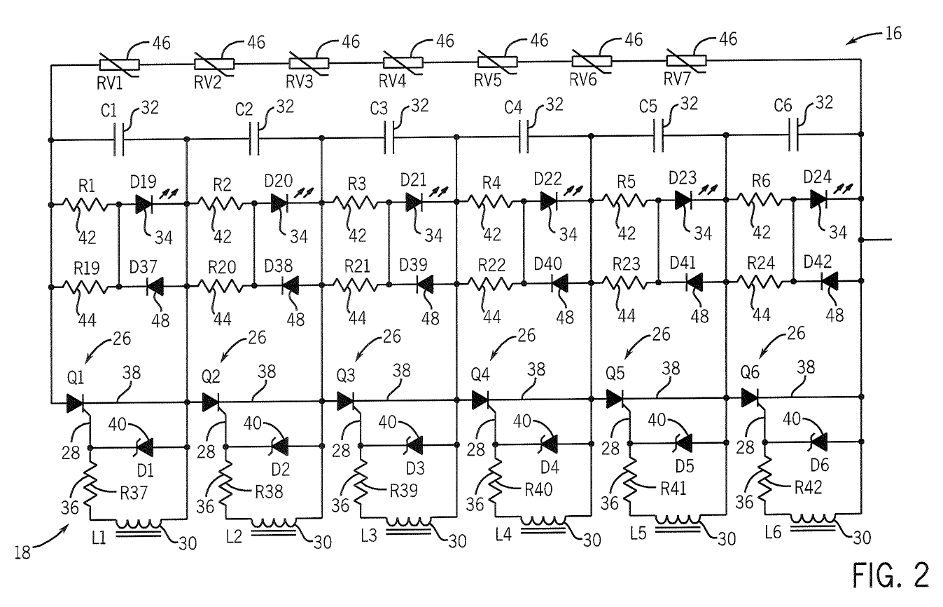

A representative configuration of one of the thyristor stacks 16 is shown in FIG. 2. It is understood that each of the thyristor stacks 16 is similarly configured, but for purposes of description only one thyristor stack 16 will be described. In the representative embodiment, the thyristor stack 16 includes six thyristors 26, with the gate terminal 28 of each thyristor 26 connected to a respective toroidal transformer 30. Snubber capacitors 32 are connected across each thyristor 26 to damp transients. Additionally, each thyristor 26 has an LED 34 that provides a visual indication of the operating status of the associated thyristor 26. Specifically, when a thyristor is not functioning properly, its associated LED will not illuminate, thus signaling an onlooker that an operational issue may be present. In addition, diodes 48 are connected in antiparallel across each LED 34 to protect the LEDs from reverse bias.

Each toroidal transformer 30 is associated with a low resistance power resistor 36 that is connected in series with each gate 28 of the thyristors 26. The toroidal transformers 30 and associated power resistors 36 provide a current pulse for triggering the thyristors 26. In one embodiment, each transformer has five turns and is designed to convert a 45 A, 525 V waveform into an 8.5 A low voltage pulse at each thyristor gate 28. A zener diode 40 is connected across the gate 28 and the cathode 38 of each thyristor 26 to provide overvoltage protection for the thyristor gates 28. As also shown in FIG. 2, each thyristor 26 is associated with a pair of ballast resistors 42, 44 that provide voltage division. Varistors 46, which in one embodiment are metal oxide varistors, are attached across the group of thyristors 16. In this representative embodiment, the varistors 46 are designed to clamp voltages in excess of 35 kV; however, it is understood that the varistors could clamp voltages at other values. Thus, for a full voltage potential of 100 kV, no group of thyristors should see more than 25.0 kV.

Each toroidal transformer 30 is fired by a trigger box 24, FIG. 1, which contains a driver circuit that is schematically shown in FIG. 3. The driver circuit 50 includes an isolation transformer 52 that is connected to an AC input 54. The output of the isolation transformer 52 is fed to a power transformer 55 and a full-wave rectifier 56 that charges capacitor 58. In one embodiment, the capacitor 58, which may include multiple capacitors arranged as a capacitor bank, is charged to 525 VDC. The driver circuit 50 also includes a fiber optic receiver 60 that accepts a clocked trigger input pulse 62 that latches silicon controlled rectifier (SCR) 64. When the SCR 64 is latched, a pulse is output at terminal 66 that is connected to the input (through the center) of each toroidal transformer 30, FIG. 2. Resistor 68 allows control of the peak current of the output pulse. Resistor 70 auto commutates the SCR 64.

The fiber optic receiver 60 is powered by a 15 VDC power supply 72 that is powered by AC power fed at input 74 in a known manner to provide a DC input to the receiver 60. A copper shield 76 or similarly electrically isolating component is placed between the fiber optic receiver 60 and the pulse generating components (transformer 55, rectifier 56, capacitor 58, and SCR 64). Metal oxide varistor 78 provides overvoltage protection for the input of DC supply 72. Transient voltage suppressors 80 provide protection against overvoltage spikes at the output of the DC supply that may affect the operation of the fiber optic receiver 60. Transient voltage suppressors 82 protect the trigger input clock signal against overvoltage. Transient voltage suppressors 84 protect the timer 60 output and SCR 64 gate input from overvoltage. Metal oxide varistors 86 protect the SCR 64 output from voltage spikes as well as providing general overvoltage protection for the entire driver circuit 50.

In one embodiment, the output pulse available at terminal 66 has a peak output current of approximately 45 A, with a rise time of 1.0 microsecond and a decay of 150 microseconds. The output pulse is received through the center of the toroidal transformers 30, which convert the signal to a low voltage pulse sufficient to bias the gates of each thyristor. The microsecond rise time is conserved and the thyristors are triggered substantially simultaneously.

The present inventor has found that performance of the high voltage modulator switch is improved with the aforementioned copper shielding of the fiber optic receiver from the pulse generating components. Additionally, performance was found to be improved when the output pulse from the trigger box was fed through the toroidal transformers using low inductance twisted output cabling.

Prototype testing was conducted using eighteen thyristors grouped into three equally sized stacks of six thyristors. The test results were favorable as the trigger box repeatedly switched the thyristors at 100 kV to provide 10 kJ of energy. Additionally, a fast rising current pulse with a peak of approximately 38 A was also realized for a test load resistance of 2700Ω at 100 kV, thereby providing further evidence of the functionality of the tested modulator switch.

Additional testing was conducted using a modulator switch composed of four stacks of thyristors, with each stack consisting of six thyristors. Similar to the 3-stack modulator switch that was tested, the four-stack modulator switch was found to be successful at repeatedly switching 100 kV of potential. Further, the additional thyristors provided an additional energy output as the 4-stack modulator switch was found to be capable of providing 70 kJ of energy.

It is understood that the circuit configurations described herein are representative and that other circuit configurations are possible and within the scope of the invention. Further, it is understood that the circuits described herein may include additional components not explicitly described that one skilled in the art may find improves circuit performance and/or reliability. Such modifications are considered within the scope of the invention.

Various modes of carrying out the invention are contemplated as being within the scope of the following claims particularly pointing out and distinctly claiming the subject matter, which is regarded as the invention.

I claim:

1. A driver circuit configured to fire multiple thyristors substantially simultaneously, comprising:
a power input;
a capacitor electrically connected to the power input;
a rectifier electrically associated with the capacitor; and
a clocked trigger that latches the rectifier to the capacitor to provide a pulsed input trigger to each of the multiple thyristors simultaneously.

2. The driver circuit of claim 1 wherein the power input is an AC power input and further comprising a full-wave rectifier interconnected between the AC power input and the capacitor.

3. The driver circuit of claim 2 wherein the full-wave rectifier is configured to charge the capacitor to approximately 525 VDC.

4. The driver circuit of claim 1 wherein the rectifier is a silicon controlled rectifier.

5. The driver circuit of claim 1 wherein the clocked trigger is a fiber optic receiver having a fiber optic connected to a clock and an output connected to the rectifier.

6. The driver circuit of claim 5 wherein each of the multiple thyristors has an input connected to a respective toroidal transformer, and wherein the output of the rectifier is connected through each toroidal transformer.

7. The driver circuit of claim 1 wherein the rectifier has an output connected through each to each of the toroidal transformers, and wherein the output includes a low inductance twisted output cable.

8. The driver circuit of claim 1 further comprising shielding between the clocked trigger and the rectifier.

9. A switching device configured to switchably connect a load to a power supply of at least 100 kV, comprising:
a plurality of switching devices connected in series, each of the switching devices having an input connected to the power supply, an output connected to a load, and a gate;
a plurality of zener diodes, wherein a zener diode is connected across the gate and the output and has a breakover voltage level selected to protect the switching device to which it is connected;
a plurality of transformers, wherein each of the transformers is coupled to the gate of a respective switching device; and
a driver circuit connected to the plurality of transformers and configured to provide a driving pulse to the plurality of transformers substantially simultaneously, wherein the driving pulse causes each transformer to forward bias the gate of each switching device.

10. The switching device of claim 9 wherein each switching device is a thyristor.

11. The switching device of claim 9 wherein the plurality of switching devices are arranged into multiple groups and further comprising an over-voltage clamp attached across each group of switching devices.

12. The switching device of claim 11 wherein each over-voltage clamp is designed to limit the voltage across a respective group of switching devices to no more than 35 kilovolts.

13. The switching device of claim 12 wherein each over-voltage clamp is a metal oxide varistor.

14. The switching device of claim 9 further comprising an LED associated with each switching device, the LED configured to provide a visual indication of operating status of the switching device.

15. The switching device of claim 9 wherein the plurality of switching devices includes at least 18 switching devices.

16. The switching device of claim 15 wherein the plurality of switching devices includes 24 switching devices.

17. A high power modulator switch for switching voltages in excess of 50 kV, comprising:
groups of thyristors connected between a power supply and a load;
a toroidal transformer connected to the gate of each thyristor; and
a driver circuit having a clocked input and an output connected through each of the toroidal transformers, the driver circuit configured to provide a pulse to each toroidal transformer so that each thyristor is switched from a non-conductive state to a conductive state substantially simultaneously.

18. The high power modulator switch of claim 17 wherein the driver circuit further has an AC power input, a transformer, a full-wave rectifier a capacitor that is charged by the full-wave rectifier, and an SCR that is triggered to latch onto the capacitor to provide the pulse to each of the toroidal transformers.

19. The high power modulator switch of claim 18 wherein the driver circuit further comprises at least one varistor that provides overvoltage protection for the SCR.

20. The high power modulator switch of claim 18 wherein the driver circuit further includes a fiber optic receiver having an input that receives a clocked signal and an output connected to the SCR.

21. The high power modulator switch of claim 20 wherein the driver circuit includes a copper shield between the SCR and the fiber optic receiver.

22. The high power modulator switch of claim 17 wherein each thyristor has a gate terminal, an anode terminal, and a cathode terminal, and further comprising a zener diode connected across the gate terminal and the cathode terminal, wherein the zener diode has a breakover voltage level selected to protect the thyristor gate to which it is connected.
